(19) United States
(12) Patent Application Publication
(10) Pub. No.: US 2020/0357778 A1
(43) Pub. Date: Nov. 12, 2020

(54) STRUCTURE OF PACKAGING MODULE AND METHOD FOR MAKING PACKAGING MODULE

(71) Applicants: SHUNSIN TECHNOLOGY (ZHONG SHAN) LIMITED, Zhongshan (CN); ShunSin Technology Holdings Limited Taiwan Branch, New Taipei City (TW)

(72) Inventor: JUN-YI XIAO, Shenzhen (CN)

(21) Appl. No.: 16/553,612

(22) Filed: Aug. 28, 2019

(30) Foreign Application Priority Data
May 6, 2019 (CN) 201910372116.0

(51) Int. Cl. H01L 25/10; H01L 25/00; H01L 23/31; H01L 21/56

(52) U.S. Cl. CPC H01L 25/105; H01L 25/50; H01L 2225/1041; H01L 21/565; H01L 23/3121

(57) ABSTRACT

A structure of a packaging module includes a top substrate, a bottom substrate, a first component, at least one interposer, and a first molding compound. The top substrate has a first side. The bottom substrate has a second side facing the first side of the top substrate. The first component is disposed on the first side of the top substrate or the second side of the bottom substrate. At least one interposer connects to the first side of the top substrate and the second side of the bottom substrate and surrounds the first component to form a first cavity between the top substrate and the bottom substrate. The first molding compound is injected into the first cavity to cover the first and other components.

### CROSS REFERENCE TO RELATED APPLICATIONS

This Application claims priority of China Patent Application No. 201910372116.0, filed on May 6, 2019, the entirety of which is incorporated by reference herein.

### FIELD

The application relates in general to a packaging structure and a packaging method, and in particular to a structure of system in package module and a method of packaging system in package module.

### BACKGROUND

Semiconductor components are widely used in various electronic applications such as personal computers, mobile phones, digital cameras, and other electronic devices. The integration density of various types of electronic components (such as transistors, diodes, resistors, capacitors, etc.) can be increased by reducing the size of the smallest components, which allows more components to be integrated into a given area. However, in the existing packaging technology, solder joints of Package on Package (PoP) and Surface-mount technology (SMT) are relatively weak, and there is a risk of solder ball breakage during a drop test. In addition, in practical applications, it is often necessary to apply glue in the gap between the stacks, thereby the cost may be increased. Increasing the reliability and utilization of the packaging may be problematic.

### BRIEF DESCRIPTION OF THE DRAWINGS

Implementations of the present disclosure will now be described with reference to the attached figures.

FIG. 1 is a schematic diagram of the structure of a packaging module in accordance with an embodiment of the present disclosure;

FIG. 2A and FIG. 2B are schematic diagrams of configurations of an interposer in the structure of FIG. 1 in accordance with one or more embodiments of the present disclosure;

FIG. 3 is a schematic diagram of the structure of a packaging module in accordance with another embodiment of the present disclosure;

FIG. 4 is a flow chart of a method for making the packaging structure in accordance with an embodiment of the present disclosure;

FIG. 5A, FIG. 5B, FIG. 5C, and FIG. 5D are cross-sectional views showing implementation of the method of FIG. 4 in accordance with an embodiment.

### DETAILED DESCRIPTION

Further areas to which the present disclosure can be applied will become apparent from the detailed description provided herein. It should be understood that the detailed description and specific examples, while indicating exemplary embodiments, are intended for purposes of illustration only and are not intended to limit the scope of the claims.

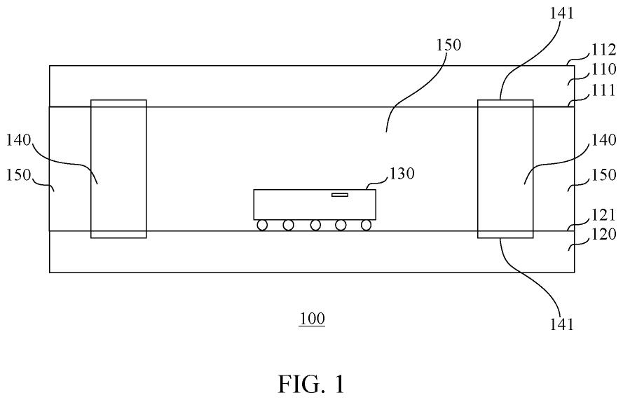

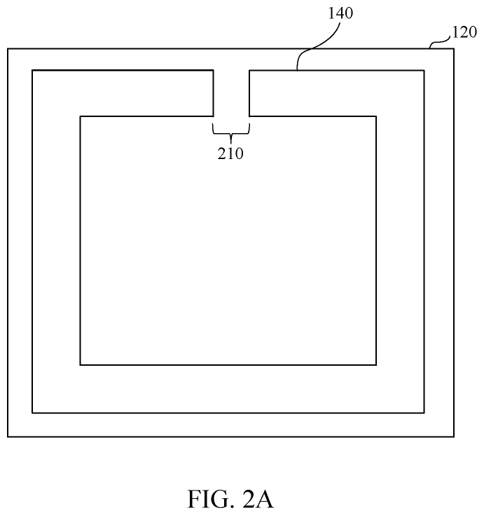

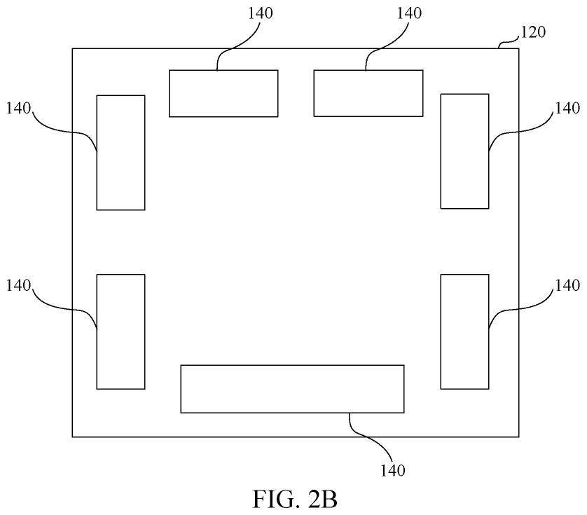

FIG. 1 shows structure of a packaging module in accordance with an embodiment of the disclosure. The structure of the packaging module 100 includes at least one top substrate 110, a bottom substrate 120, a first component 130, an interposer 140, and a first molding compound 150. The top substrate 110 has a first side 111 and a third side 112 opposite to the first side 111. The bottom substrate 120 has a second side 121. The first side 111 of the top substrate 110 faces the second side 121 of the bottom substrate 120. Component 130 can be any component such as a chip, a passive component, a capacitor, a resistor, an antenna, or a connector. The component 130 is provided on the first side 111 of the top substrate 110 or the second side 121 of the bottom substrate 120 through a Surface-mount technology (SMT) to electrically connect with at least one of the top substrate 110 and the bottom substrate 120. The interposer 140 is composed of a conductive material, such as a copper wire covered with an insulating material, which surrounds the first component 130 and has a height higher than that of the first component 130. The interposer 140 connects to the top substrate 110 and the bottom substrate 120 through SMT, such that the top substrate 110 is electrically connected to the bottom substrate 120 through the interposer 140. For example, as shown in FIG. 1, the interposer 140 is soldered on the second side 121 of the bottom substrate 120 and the first side 111 of the top substrate 110 through the solder paste 141. The first cavity formed by the top substrate 110, the bottom substrate 120, and the interposer 140 has at least one opening (as shown in FIGS. 2A and 2B), so that an injection device can inject the first molding compound 150 into the first cavity through the opening. The first molding compound 150 can be an Epoxy Molding Compound, which covers the first component 130 and the areas of the top substrate 110 and the bottom substrate 120 not covered by the first component 130. The compound 150 surrounds the interposer 140 for protecting the circuit board and components.

FIG. 2A and FIG. 2B show configurations of the interposer 140 in the structure in accordance with one or more embodiments. As shown in FIG. 2A, the opening is a gap (labeled “210” in the figure) which is not covered by the interposer 140, so that the injection device can inject the first molding compound 150 between the top substrate 110, the bottom substrate 120, and the interposer 140 through the gap 210. In another embodiment, because each of the two interposers 140 may form one gap, the number of the interposers 140 provided between the top substrate 110 and the bottom substrate 120 as shown in FIG. 2B is seven. That is, the number of the openings shown in FIG. 2B is seven. It should be noted that the configurations of the interposer 140 as shown in FIGS. 2A and 2B are only examples, and the interposer 140 may be provided adjacent to the first component 130 or along the edge of the top substrate 110 and the bottom substrate 120, etc., it is not limited thereto.

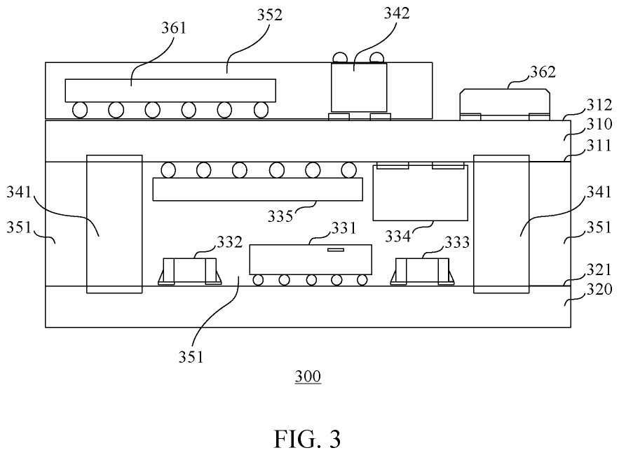

FIG. 3 is a schematic diagram of the structure in accordance with another embodiment. As shown in the FIG. 3, the elements 311-333 are provided on the second side 321 of the bottom substrate 320 through SMT technology, and likewise for the elements 334 and 335 on the first side 311 of the top substrate. Similarly, the interposer 341 electrically connects to the first side 311 of the top substrate 310 and the second side 321 of the bottom substrate 320 through SMT. In this embodiment, the structure 300 further includes second elements 361, 362 and an interposer 342 provided on the third side 312 of the top substrate 310. As shown in FIG. 3, the second component 361 is a chip electrically connected by SMT to the third side 312 of the top substrate 310 and is covered by the second molding compound 352. The lower side of the interposer 342 also electrically connects by SMT to the third side 312 of the top substrate 310, and the sides are surrounded by the second molding compound 370. The upper side of the interposer 342 is not covered by the second molding compound 352, such that an external component or device can electrically connect to the third side 312 of the top substrate 310 through a solder ball on the upper side of the interposer 342. In addition, the second component 362 is a connector which is used to connect with the external device, such that it is not covered by the second molding compound 370. In other words, the second molding compound 352 covers the third side 312 of the whole top substrate 310 or only covers a portion of the top substrate according to user demand. Before the second molding compound 352 is formed, the mold is first joined to the third side 312 of the top substrate 310 to form a second cavity having at least one opening, and then the injection device injects the second molding compound 352 through the opening. At the final step, the mold is separated from the top substrate 310 after a cooling stage.

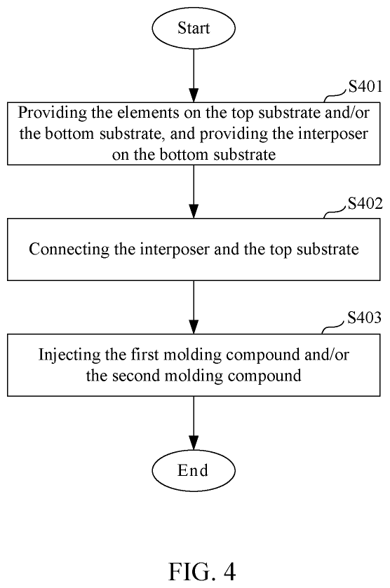

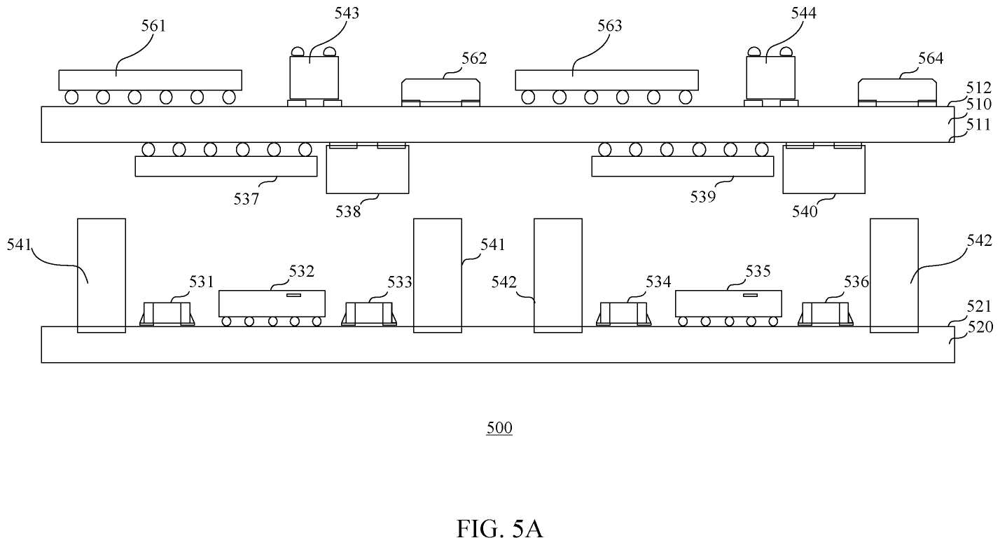

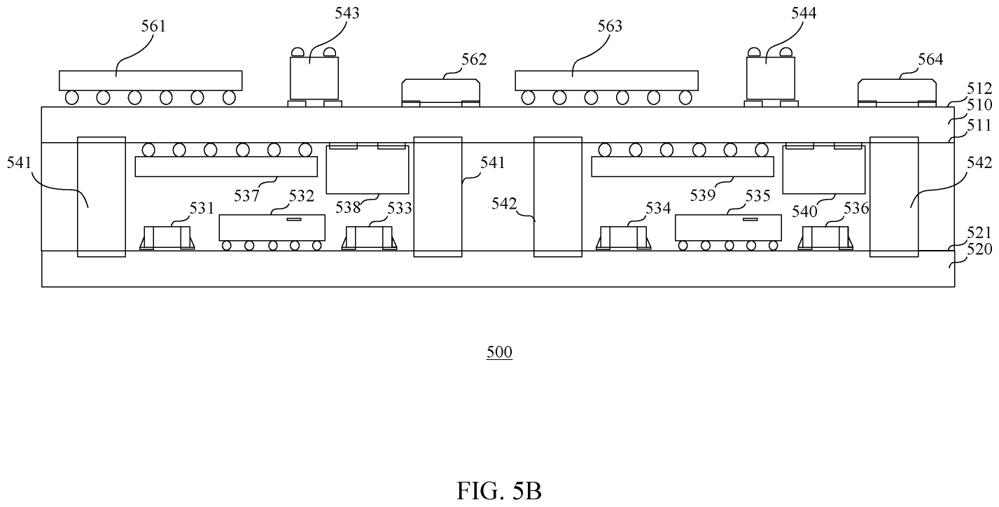

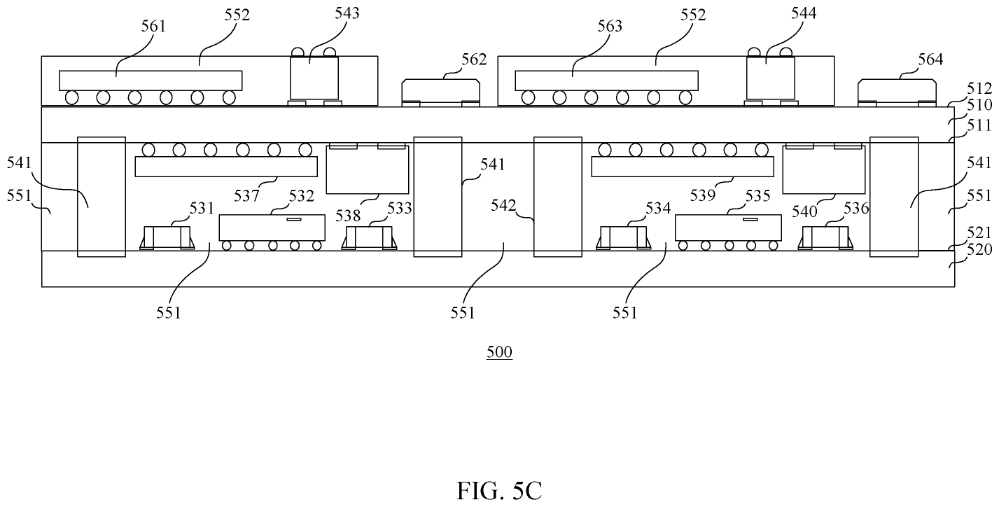

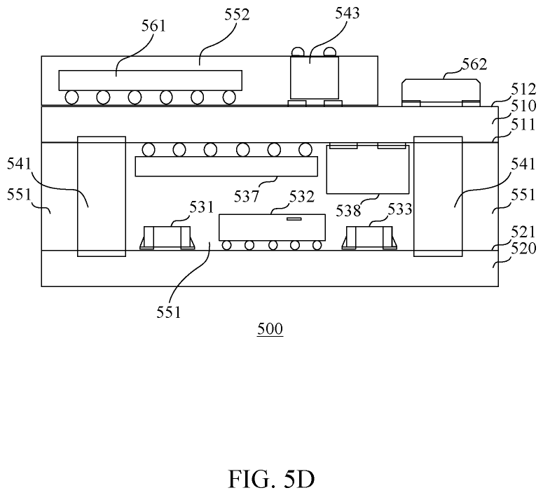

FIG. 4 is a flow chart of a method of making the package module in accordance with an embodiment. FIG. 5A, FIG. 5B, FIG. 5C, and FIG. 5D are cross-sectional views of implementing the method in accordance with an embodiment. Referring to FIG. 5A., at step S401, the first components 531-536 and the interposer 541, 542 are provided on the second side 521 of the bottom substrate 520 by SMT, the first components 537-540 are provided by SMT on the first side 511 of the top substrate 510, and the second elements 561, 562 and the interposer 543, 544 are provided by SMT on the third side 512 of the top substrate 510. Referring to FIG. 5B, at step S402, the top substrate 510 connects by SMT to the interposers 541, 542 provided on the second side 521 of the bottom substrate 520, so that the top substrate 510 electrically connects to the bottom substrate 520 through the interposers 541, 542, and the first cavity is formed between the top substrate 510 and the bottom substrate 520. Referring to FIG. 5C, at step S403, the first molding compound 551 is injected in the first cavity between the top substrate 510 and the bottom substrate 520 to cover the first element 531-540 provided on the top substrate 510 and the bottom substrate 120. In addition, for the second component 561 and the interposer 542 provided on the third side 512 of the top substrate 510, the mold (not shown) is first bonded to the third side 512 of the top substrate 510 to form the second cavity having at least one opening before the second molding compound is injected. The injection device injects the second molding compound 552 in the second cavity through the opening. Finally, the mold is separated from the top substrate 310 after the cooling stage, so that the second molding compound 552 covers the second elements 561, 536 on the third side 512 of the top substrate 510 and surrounds the interposer 543. In the embodiments of FIGS. 5A-5C, the finished product is further cut into half to form a single packaging structure as shown in FIG. 5D because the finished product includes two packages.

It should be noted that although the method as described above has been described through a series of steps or blocks of a flowchart, the process is not limited to any order of the steps, and some steps may be different from the order of the remaining steps or the remaining steps can be done at the same time. In addition, those skilled in the art should understand that the steps shown in the flowchart are not exclusive, other steps may be included, or one or more steps may be deleted without departing from the scope.

As described above, according to the embodiments, a structure of packaging module and a method of making the packaging module are provided by injecting a molding compound between a top substrate and a bottom substrate or covering the area having components on the substrate. This improves reliability, sealing of the package, waterproof performance, and package utilization.

It will be apparent to those skilled in the art that various modifications and variations can be made to the structure disclosed without departing from the scope or spirit of the claims. In view of the foregoing, it is intended that the present disclosure covers modifications and variations, provided they fall within the scope of the following claims and their equivalents.

What is claimed is:

1. A structure of system in package module, comprising:
a top substrate comprising a first side;
a bottom substrate comprising a second side facing the first side of the top substrate;
a first component disposed on the first side of the top substrate or the second side of the bottom substrate;
at least one interposer connecting to the first side of the top substrate and the second side of the bottom substrate and surrounding the first component to form a first cavity between the top substrate and the bottom substrate; and
a first molding compound filled in the first cavity, the first molding compound covering the first component.

2. The structure of system in package module as claimed in claim 1, wherein at least one opening connecting to the first cavity is formed between the interposer, the top substrate and the bottom substrate, such that the first cavity is filled with the first molding compound through the opening by an injection molding method.

3. The structure of system in package module as claimed in claim 1, further comprising:
a second component disposed on a third side of the top substrate, and covered by a second molding compound, wherein the third side is located on a side opposite to the first side of the top substrate.

4. The structure of system in package module as claimed in claim 3, wherein the first component is disposed on the first side of the top substrate or the second side of the bottom substrate by a Surface-mount technology (SMT) method, and the at least one interposer connects the first side of the top substrate and the second side of the bottom substrate through the SMT method, such that the top substrate and the bottom substrate is electrically connected through the at least one interposer.

5. The structure of system in package module as claimed in claim 3, wherein the first molding compound and the second molding compound are Epoxy Molding Compound.

6. A method of packaging system in package module, comprising:
providing a first component on a first side of a top substrate or a second side of a bottom substrate, wherein the first side of the top substrate faces the second side of the bottom substrate;
providing at least one interposer on the second side of the bottom substrate, wherein the at least one interposer surrounds the first component;
connecting the at least one interposer and the first side of the top substrate to form a first cavity between the top substrate and the bottom substrate;
filling a first molding compound in the first cavity to cover the first component.

7. The method of packaging system in package module as claimed in claim 6, further comprising:
providing at least one opening connecting to the first cavity between the interposer, the top substrate and the bottom substrate, wherein the first cavity is filled with the first molding compound through the opening by an injection molding method.

8. The method of packaging system in package module as claimed in claim 6, further comprising:
providing a second component covered by a second molding compound on a third side of the top substrate, wherein the third side is located on a side opposite to the first side of the top substrate.

9. The method of packaging system in package module as claimed in claim 8, further comprising:
providing a second cavity between the third side of the top substrate and a mold;
filling the second molding compound in the second cavity by an injection molding method to cover and/or surround the second component;
wherein the first molding compound and the second molding compound are Epoxy Molding Compound.

10. The method of packaging system in package module as claimed in claim 9, further comprising:
providing the first component on the first side of the top substrate or the second side of the bottom substrate by a Surface-mount technology (SMT) method;
connecting the at least one interposer, the first side of the top substrate, and the second side of the bottom substrate by the SMT method, such that the top substrate and the bottom substrate is electrically connected through the at least one interposer.
